(19) United States
(12) Patent Application Publication
(10) Pub. No.: US 2017/0330693 A1
(43) Pub. Date: Nov. 16, 2017

(54) Interlayer Additives For Highly Efficient And Hysteresis-Free Perovskite-Based Photovoltaic Devices

(71) Applicant: Board of Trustees of Michigan State University, East Lansing, MI (US)

(72) Inventors: Richard R. LUNT, III, Williamston, MI (US); Lili WANG, East Lansing, MI (US)

(73) Assignee: Board of Trustees of Michigan State University, East Lansing, MI (US)

(21) Appl. No.: 15/592,348

(22) Filed: May 11, 2017

Related U.S. Application Data
(60) Provisional application No. 62/334,563, filed on May 11, 2016.

(51) Int. Cl. H01G 9/20; H01L 51/42; H01L 51/00; H01G 9/00; H01L 51/44

(52) U.S. Cl. CPC H01G 9/2013; H01L 51/442; H01L 51/4253; H01L 51/0077; H01G 9/0032; H01L 51/0026; H01G 9/2018; H01L 51/0037

(57) ABSTRACT

A photovoltaic device is provided. The photovoltaic device includes a metal salt layer disposed adjacent to a perovskite layer. The metal salt layer diffuses into the perovskite layer. Methods for fabricating the photovoltaic device are also provided.

### CROSS-REFERENCE TO RELATED APPLICATIONS

This application claims the benefit of U.S. Provisional Application No. 62/334,563, file on May 11, 2016. The entire disclosure of the above application is incorporated herein by reference.

### GOVERNMENT SUPPORT

This invention was made with government support under DE-SC0010472 awarded by the U.S. Department of Energy. The government has certain rights in the invention.

### FIELD

The present disclosure relates to a new architecture and method of fabricating highly efficient and hysteresis-free perovskite-based photovoltaic devices.

### BACKGROUND

This section provides background information related to the present disclosure which is not necessarily prior art.

Hybrid organic-inorganic halide perovskite materials have emerged as a highly promising candidate for low-cost solar photovoltaic (PV) applications. Due to their narrow and tunable band-gap, high absorbance, low exciton binding energy, and high carrier mobility, overall power conversion efficiency has been improved from a modest 3.8% in liquid-electrolyte configuration to over 20% in an all solid-state architecture. However, there are still several challenges to be addressed before such solid state architecture can displace other PV technologies available in the market. One of the most challenging challenges is to understand and suppress the hysteresis phenomenon in current-voltage (I-V) characteristics, which make it difficult to accurately evaluate a device's performance and track power points.

Often, device performance of these perovskites have been shown to be dependent on scan rate, scan direction, light soaking and external bias conditions. These effects have been explained by a combination of factors including: charge accumulation, which is caused by trap states, ion migration, or unbalanced electron and hole extraction or collection at the interfaces and the potential for ferroelectric transitions. To solve this problem, different approaches have been investigated. The most effective methods for solving the problem are aimed at either improving the charge transport or decreasing and passivating crystal defects in the perovskite layer. Crystal defects such as self-interstitial atom and vacancies have been considered as one of the main reasons leading to trap states and providing ion migration pathways that provide unreliable I-V and further induce instability. One of the most probable defects in such hybrid perovskite films are iodide vacancies which have the lowest formation energy and relatively lower migration energy. As both methylammonium iodide and methylammonium chloride sublime at relatively low temperature, the amount of halide vacancies left behind in the perovskite film likely cannot be neglected. Therefore, a key strategy for suppressing hysteresis is needed to improve the crystallinity and decrease the halide vacancy defects of perovskite films.

### SUMMARY

This section provides a general summary of the disclosure, and is not a comprehensive disclosure of its full scope or all of its features.

The current technology provides a photovoltaic device. The photovoltaic device includes a substrate having a first surface and a second opposing surface, a first electrode disposed directly on at least one of the first surface or the second surface of the substrate, a layer having a perovskite material, a layer having a metal salt, and a second electrode, wherein the layer having a metal salt and the layer having a perovskite material are located between the first electrode and the second electrode. In various aspects, the photovoltaic device also includes a carrier transport layer, wherein the carrier transport layer is disposed directly on the layer having a perovskite material. The carrier transport layer includes either at least one electron transport layer or at least one hole transport layer. When the carrier transport layer is an electron transport layer, the second electrode is a cathode and the electron transport layer is disposed on the cathode, such that the electron transport layer is located between the layer having a perovskite material and the cathode. In some embodiments, the device further includes a carrier transport layer disposed directly on the layer having a metal salt, such that the layer having a metal salt is located between the layer having a perovskite material and the carrier transport layer.

The current technology also provides a method for fabricating a doped photovoltaic device. The method includes sequentially disposing the following layers onto a substrate: a layer having a first electrode, a layer having at least one metal salt, a layer having a perovskite material, and a layer having a second electrode. The layer having a perovskite material is disposed directly on the layer having at least one metal salt, such that the layer having at least one metal salt is partially or completely diffused into the layer having a perovskite material.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1A is an illustration of a device according to various aspects of the current technology;

FIG. 1B is an exploded view of the device of FIG. 1A;

FIG. 2 is an illustration of a second device according to various aspects of the current technology;

FIG. 3 is an illustration of a third device according to various aspects of the current technology;

FIG. 4 is an illustration of a fourth device according to various aspects of the current technology;

FIG. 5 is an illustration of a fifth device according to various aspects of the current technology;

FIG. 6 is a graph showing optical constants of perovskite for optical modeling, where n is an index of refraction and k is an extinction coefficient;

FIG. 7A is an illustration of a device fabricated according to various aspects of the current technology;

FIG. 7B is a scanning electron micrograph of a device fabricated according to various aspects of the current technology;

FIG. 7C is an illustration showing a fabrication method, wherein a NaI layer acts as a template for perovskite crystallization and then NaI slowly diffuses into the perovskite to fill iodine vacancies and to suppress hysteresis;

FIG. 8A is a graph showing x-ray diffraction patterns of samples prepared without NaI and with NaI;

FIG. 8B is scanning electron micrograph of a sample prepared without NaI, wherein the scale bar is 1 μm;

FIG. 8C is scanning electron micrograph of a sample prepared with NaI, wherein the scale bar is 1 μm;

FIG. 9A shows current-voltage (J-V) curves for devices prepared with or without NaI, wherein the close symbols represent forward scan and the open symbols represent reverse scan;

FIG. 9B shows external quantum efficiency (EQE) curves for devices prepared with or without NaI;

FIG. 9C is a histogram of power conversion efficiency (PCE) for 80 separate devices prepared with or without NaI, respectively;

FIG. 10A shows time-of-flight secondary ion mass spectrometry (TOF-SIMS) curves of samples prepared with NaI before annealing;

FIG. 10B shows TOF-SIMS curves of samples prepared with NaI after annealing;

FIG. 10C shows TOF-SIMS curves of samples prepared without NaI after annealing;

FIG. 11 shows time-of-flight secondary ion mass spectrometry (TOF-SIMS) curves of samples, wherein chlorine has been eliminated after annealing whether prepared with NaI or without NaI;

FIG. 12A shows current-voltage (J-V) curves for representative devices prepared with 0.7 M of precursor solution, wherein the concentration of NaI solution used for coating NaI layer are 50 mg/mL, 100 mg/mL and 200 mg/mL, respectively, and wherein the close symbols represent forward scan and the open symbols represent reverse scan;

FIG. 12B shows J-V curves for representative devices prepared with different concentrations of precursor solution and optimized NaI concentration, wherein the close symbols represent forward scan and the open symbols represent reverse scan;

FIG. 13A shows current-voltage (J-V) curves for representative devices prepared with 0.55 M of precursor solution, wherein the concentration of NaI solution used for coating NaI layer are 50 mg/mL, 100 mg/mL and 200 mg/mL, respectively, and wherein the close symbols represent forward scan and the open symbols represent reverse scan;

FIG. 13B shows current-voltage (J-V) curves for representative devices prepared with 0.4 M of precursor solution, wherein the concentration of NaI solution used for coating NaI layer are 50 mg/mL, 100 mg/mL and 200 mg/mL, respectively, and wherein the close symbols represent forward scan and the open symbols represent reverse scan;

FIG. 14A shows current-voltage (J-V) parameters including efficiency for representative devices prepared with 0.7 M, 0.55 M and 0.4 M of precursor solution, wherein the concentration of NaI solution used for coating NaI layer are 50 mg/mL, 100 mg/mL and 200 mg/mL, respectively, and the close symbols represent forward scan and the open symbols represent reverse scan;

FIG. 14B shows J-V parameters including short circuit current density (Jsc) for representative devices prepared with 0.7 M, 0.55 M and 0.4 M of precursor solution, wherein the concentration of NaI solution used for coating NaI layer are 50 mg/mL, 100 mg/mL and 200 mg/mL, respectively, and the close symbols represent forward scan and the open symbols represent reverse scan;

FIG. 14C shows J-V parameters including open circuit voltage (Voc) for representative devices prepared with 0.7 M, 0.55 M and 0.4 M of precursor solution, wherein the concentration of NaI solution used for coating NaI layer are 50 mg/mL, 100 mg/mL and 200 mg/mL, respectively, and the close symbols represent forward scan and the open symbols represent reverse scan;

FIG. 14D shows J-V parameters including fill factor (FF) for representative devices prepared with 0.7 M, 0.55 M and 0.4 M of precursor solution, wherein the concentration of NaI solution used for coating NaI layer are 50 mg/mL, 100 mg/mL and 200 mg/mL, respectively, and the close symbols represent forward scan and the open symbols represent reverse scan;

FIG. 15A shows a modeled photon absorption rate for an as-fabricated perovskite device;

FIG. 15B shows a modeled generation rate at a wavelength of 400 nm;

FIG. 15C shows a modeled generation rate at a wavelength of 550 nm;

FIG. 15D shows a modeled generation rate at a wavelength of 725 nm;

FIG. 16A shows photographs of vials containing different amounts of NaI dissolved in dimethylformamide (DMF);

FIG. 16B shows photographs of a precursor solution without NaI and with 25 mg/mL NaI;

FIG. 17 shows current-density (J-V) curves for representative devices prepared by directly adding different amounts of NaI into 1 mL of 0.7 M precursor solution, wherein the close symbols represent forward scan and the open symbols represent reverse scan;

FIG. 18 shows current-density (J-V) curves for representative devices prepared by (a) dissolving NaI in different solvents (methanol (NaBr_F) and water (NaI_F)) and (b) by using aqueous solution of different salts (NaI, NaCl, Nabr, and Csl), wherein the close symbols represent forward scan and the open symbols represent reverse scan, and wherein NaCl, NaBr and Csl solutions used for device fabrication are aqueous solutions because of the low solubility of these salts in methanol;

FIG. 19A shows x-ray diffraction patterns of samples prepared with NaI co-deposition by directly adding different amounts of NaI into precursor solution;

FIG. 19B shows grain size distribution of perovskite films prepared with co-deposition at different NaI concentrations, wherein the dotted line indicates the instrument resolution limit;

FIG. 19C shows d-spacing changes with applied bias in samples prepared with or without NaI, wherein the linear trendlines are visual guides;

FIG. 19D is a photograph showing the appearance of a sample prepared without NaI after applying bias;

FIG. 19E is a photograph showing the appearance of a sample prepared with NaI after applying bias;

FIG. 20A shows XRD patterns for a device measured when bias is applied on a tested area, wherein the device is fabricated without NaI;

FIG. 20B is an enlarged view of the XRD patterns shown in FIG. 20A;

FIG. 20C shows XRD patterns for a device measured when bias is applied on a tested area, wherein the device is fabricated with NaI; and

FIG. 20D is an enlarged view of the XRD patterns shown in FIG. 20A.

Corresponding reference numerals indicate corresponding parts throughout the several views of the drawings.

### DETAILED DESCRIPTION

Example embodiments are provided so that this disclosure will be thorough, and will fully convey the scope to those who are skilled in the art. Numerous specific details are set forth such as examples of specific compositions, components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, elements, compositions, steps, integers, operations, and/or components, but do not preclude the presence or addition of one or more other features, integers, steps, operations, elements, components, and/or groups thereof. Although the open-ended term “comprising,” is to be understood as a non-restrictive term used to describe and claim various embodiments set forth herein, in certain aspects, the term may alternatively be understood to instead be a more limiting and restrictive term, such as “consisting of” or “consisting essentially of.” Thus, for any given embodiment reciting compositions, materials, components, elements, features, integers, operations, and/or process steps, the present disclosure also specifically includes embodiments consisting of, or consisting essentially of, such recited compositions, materials, components, elements, features, integers, operations, and/or process steps. In the case of “consisting of,” the alternative embodiment excludes any additional compositions, materials, components, elements, features, integers, operations, and/or process steps, while in the case of “consisting essentially of,” any additional compositions, materials, components, elements, features, integers, operations, and/or process steps that materially affect the basic and novel characteristics are excluded from such an embodiment, but any compositions, materials, components, elements, features, integers, operations, and/or process steps that do not materially affect the basic and novel characteristics can be included in the embodiment.

Any method steps, processes, and operations described herein are not to be construed as necessarily requiring their performance in the particular order discussed or illustrated, unless specifically identified as an order of performance. It is also to be understood that additional or alternative steps may be employed, unless otherwise indicated.

When a component, element, or layer is referred to as being “on,” “engaged to,” “connected to,” or “coupled to” another element or layer, it may be directly on, engaged, connected or coupled to the other component, element, or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Spatially or temporally relative terms, such as “before,” “after,” “inner,” “outer,” “beneath,” “below,” “lower,” “above,” “upper,” and the like, may be used herein for ease of description to describe one element or feature's relationship to another element(s) or feature(s) as illustrated in the figures. Spatially or temporally relative terms may be intended to encompass different orientations of the device or system in use or operation in addition to the orientation depicted in the figures.

Throughout this disclosure, the numerical values represent approximate measures or limits to ranges to encompass minor deviations from the given values and embodiments having about the value mentioned as well as those having exactly the value mentioned. All numerical values of parameters (e.g., of quantities or conditions) in this specification, including the appended claims, are to be understood as being modified in all instances by the term “about” whether or not “about” actually appears before the numerical value. “About” indicates that the stated numerical value allows some slight imprecision (with some approach to exactness in the value; approximately or reasonably close to the value; nearly). If the imprecision provided by “about” is not otherwise understood in the art with this ordinary meaning, then “about” as used herein indicates at least variations that may arise from ordinary methods of measuring and using such parameters.

In addition, disclosure of ranges includes disclosure of all values and further divided ranges within the entire range, including endpoints and sub-ranges given for the ranges. As referred to herein, ranges are, unless specified otherwise, inclusive of endpoints and include disclosure of all distinct values and further divided ranges within the entire range. Thus, for example, a range of “from A to B” or “from about A to about B” is inclusive of A and of B.

Example embodiments will now be described more fully with reference to the accompanying drawings.

The current technology provides methods for doping and fabricating hysteresis-free perovskite-based photovoltaic devices by using metal salts as interface layer additives. Such metal salt layers introduced at perovskite interfaces can provide excessive halide ions to fill vacancies formed inside the perovskite during deposition and annealing process, to improve device stability, lifetime, and efficiency. The method generates photovoltaic devices with a power conversion efficiency (PCE) ranging from about 10% to about 15%, such as, for example, a PCE of about 12.6%, and a hysteresis of equal to or less than about 10%, equal to or less than about 5%, or equal to or less than about 3%, such as, for example, a hysteresis of about 3%, 2%, 1% or less. These PCE and hysteresis values are greatly improved, up to about 90%, relative to conventional devices without the metal salt layer. Without being bound by theory, through depth resolved mass spectrometry and optical modeling, this enhancement is attributed to the reduction of iodide vacancies. These methods provide an alternative and facile route to high performance and hysteresis-free perovskite solar cells. Devices made by these methods are also provided by the current technology.

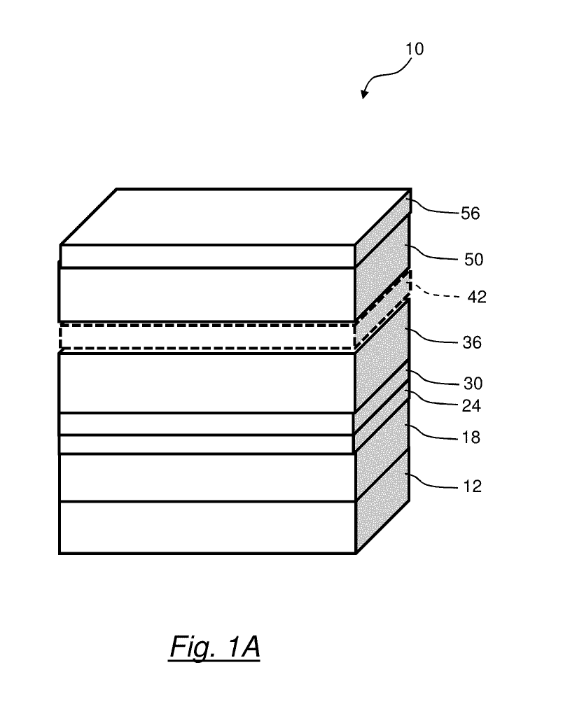

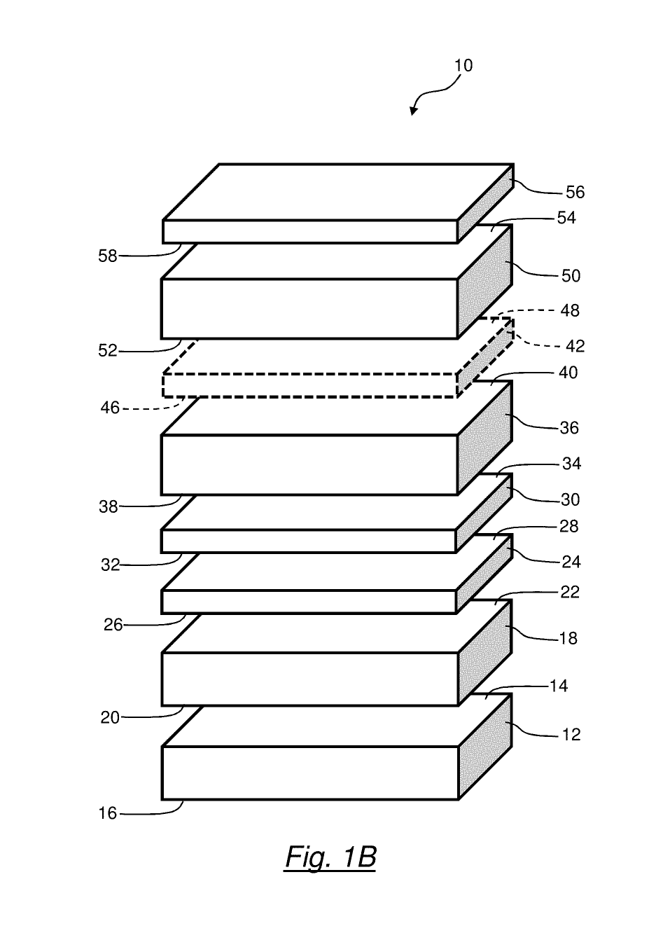

With reference to FIGS. 1A and 1B, the current technology provides a photovoltaic device 10. FIG. 1B is an exploded view of the device 10 shown in FIG. 1A. The device 10 comprises a substrate 12 having a first surface 14 and a second opposing surface 16 and a first electrode 18 disposed directly on at least the first surface 14 of the substrate 12. The electrode 18 has a first surface 20 and a second opposing surface 22. The photovoltaic device 10 also has a layer comprising a metal salt 30 having a first surface 32 and a second opposing surface 34 and a layer comprising a perovskite material 36, i.e., a light absorbing layer, having a first surface 38 and a second opposing surface 40. The photovoltaic device 10 also has a second electrode 56 having a first surface 58. The layer comprising a metal salt 30 and the layer comprising a perovskite material 36 are located between the first electrode 18 and the second electrode 56.

The substrate 12 can be composed of any material known in the art. As non-limiting examples, the substrate 12 can be composed of glass, low iron glass, plastic, poly(methyl methacrylate) (PMMA), poly-(ethyl methacrylate) (PEMA), (poly)-butyl methacrylate-co-methyl methacrylate (PBMMA), polyethylene terephthalate (PET), polyimides, such as Kapton® polyimide films (DuPont, Wilmington, Del.), amorphous silicon, crystalline silicon, stainless steel, metals, metal foils, and gallium arsenide. As discussed further below, one of the first electrode 18 or the second electrode 56 is a cathode and the other of the first electrode 18 or the second electrode 56 is an anode. The first electrode and the second electrode are composed of a material individually selected from the group consisting of a thin film of indium tin oxide (ITO), aluminum doped zinc oxide (AZO), indium zinc oxide, zinc oxide, and gallium zinc oxide (GZO), metal or ultra-thin metals, such as Al, Au, Ag, Mo, Cu, or Ni, graphene, graphene oxide, poly(3,4-ethylenedioxythiophene) polystyrene sulfonate (PEDOT:PSS), metal nanowires, such as Al, Au, or Ag nanowires, and combinations thereof. The first and second electrodes 18, 56 individually have a thickness of from about 5 nm to about 200 nm, or from about 50 nm to about 150 nm, or from about 75 nm to about 125 nm.

In various embodiments, the layer comprising a metal salt 30 is composed of at least one metal halide salt, at least one alkali metal halide salt, at least one alkaline earth metal halide salt, at least one transition metal halide salt, at least one sulfide salt, or a combination thereof. Metal halide salts are selected from the group consisting of PbX₂, SnX₂, GeX₂, AlX₃, BX₃, GaX₃, BiX₃, InX₃, SiX₄, TiX₄, SbX₅, and combinations thereof, where X is a halide or a combination of halides, wherein halides are F⁻, Cl⁻, Br, or I⁻. Alkali metal halide salts have the MX, where M is Li, Na, K, Rb, or Cs and X is a halide or a combination of halides. Exemplary metal halide salts include NaI and NaBr. Alkaline earth metal halide salts have the formula M′X2, where M′ is Be, Mg, Ca, or Sr an X is a halide. Transition metal halide salts have the formula MXₙ, where M is Mn, Fe, Co, Ni, Cr, V, or Cu; n is 1, 2, 3, 4, or 5; and X is a halide. Exemplary transition metal halide salts include MnF₃, MnF₄, MnCl₂, MnCl₃, MnBr₂, Mnl₂, FeF₂, FeF₃, FeCl₃, FeCl₂, FeBr₂, FeBr₃, Felₜ, Fel₃, CoF₂, CoF₃, CoF₄, CoCl₂, CoCl₃, CoBr₂, CoI₂, NiF₂, NiCl₂, NiI₂, CrF₂, CrF₃, CrF4, CrF5, CrF₆, CrCl₂, CrCl₃, CrCl₄, CrBr₂, CrBr₃, CrBr₄, CrI₂, CrI₃, CrI₄, VF₂, VF₃, VF₄, VF₅, VCl₂, VCl₃, VCl₄, VBr₂, VBr₃, VBr₄, VI₂, VI₃, VI₄, CuF, CuF₂, CuCl, CuCl₂, CuBr₂, CuI, and combinations thereof. Sulfide salts have the formula M₂S, M′S, M″₂S₃, or M*S₂, where M is Li, Na, K, Rb, or Cs; M′ is Be, Mg, Ca, Sr, or Pb; M″ is Bi, Al, Ga, In, or Sb; M* is Si, Ge, Sn, or Pb; and S is S, Se, or Te. Accordingly, the metal salt can include any combination of the metal salts described herein.

A perovskite is a material that has the same type of crystal structure as calcium titanium oxide (CaTiO3; i.e., naturally occurring perovskite). The crystal structure is known as the “perovskite structure” or ^{XII}A^{2+VI}B⁴⁺X²⁻₃ with oxygen in the face centers. The general formula for a perovskite compound si ABX₃, where A and B are cations of different sizes (the A cation is typically larger than the B cation) and X is an anion that bonds to both A and B. The ideal cubic-symmetry structure has the B cation in 6-fold coordination, surrounded by an octahedron of anions, and the A cation in 12-fold cuboctahedral coordination. In various embodiments, the layer comprising a perovskite material 36 includes at least one perovskite, hybrid halide perovskite, oxide perovskite, layered halide perovskite, or at least one inorganic halide perovskite. Hybrid halide perovskites have the formula ABX₃, where A is methylammonium (MA), formamidinium (FA), ethanediammonium (EA) or iso-propylammonium; B is Pb, Sn, Ge, Cu, Sr, Ti, Mn, or Zn; and X is a halide. Inorganic halide perovskites have the formula MBX₃, where M is Li, Na, K, Rb, or Cs; B is Pb, Sn, Ge, Cu, Sr, Ti, Mn, or Zn; and X is a halide. Accordingly, the perovskite material can include any combination of the perovskite materials described herein. The layer comprising a perovskite material 36 has a thickness of from about 20 nm to about 2000 nm, from about 50 nm to about 1000 nm, from about 100 nm to about 800 nm, from about 200 nm to about 600 nm, or from about 300 nm to about 400 nm.

The layer comprising a perovskite material 36 is disposed directly on the layer comprising a metal salt 30. With reference to FIG. 1B, the first surface 38 of the layer comprising a perovskite material 36 is directly disposed on the second surface 34 of the layer comprising the metal salt. Although the layer comprising a metal salt 30 initially has a thickness of from about 0.1 nm to about 100 nm, upon annealing the layer comprising the metal salt 30 at least partially diffuses in the layer comprising a perovskite material 36. Therefore, in some embodiments, the layer comprising a metal salt 30 is either partially or completely diffused into the layer comprising a perovskite material 36. Accordingly, the device 10 is doped with the metal salt. More particularly, the perovskite material of the device 10 is incorporated or doped with the metal salt.

In some embodiments, the device 10 includes an optional second layer of a metal salt 42. The optional second layer of a metal salt 42 includes any metal salt or combination of metal salts described herein. The optional second layer of metal salt 42 includes a first surface 44 and a second surface 48. When present, the first surface 46 of the second layer of a metal salt 42 is disposed directly on the second surface 40 of the layer comprising a perovskite material 36. Although the second layer comprising a metal salt 42 initially has a thickness of from about 0.1 nm to about 100 nm, upon annealing the second layer comprising the metal salt 42 at least partially diffuses in the layer comprising a perovskite material 36. Therefore, in some embodiments, the second layer comprising a metal salt 42 is either partially or completely diffused into the layer comprising a perovskite material 36.

The device 10 further comprises a first carrier transport layer 24 having a first surface 26 and an opposing second surface 28 and a second carrier transport layer 50 having a first surface 52 and an opposing second surface 54. The first carrier transport layer 24 is disposed between the layer comprising a metal salt 30 and the first electrode 18, such that the first surface 26 of the first carrier transport layer 24 is directly disposed on the second surface 22 of the first electrode and the second surface 28 of the first carrier transport layer is directly disposed on the first surface 32 of the layer comprising a metal salt 30. The second carrier transport layer 50 is disposed between the layer comprising a perovskite material 36 and the second electrode 56. For example, first surface 52 of the second carrier transport layer 50 may be directly disposed on the second surface 40 of the layer comprising a perovskite material 36 or the first surface 52 of the second carrier transport layer 50 may be directly disposed on the second surface 48 of the optional second layer comprising a metal salt 42, when present. The second surface 54 of the second carrier transport layer 50 is directly disposed on the first surface 58 of the second electrode 56.

The first carrier transport layer 24 is either a hole transport layer or an electron transport layer and the second carrier transport layer 50 is the other of a hole transport layer or an electron transport layer. Therefore, the first carrier transport layer 24 and the second carrier transport layer 50 do not include the same materials or sublayers. Accordingly, when one of the first carrier transport layer 24 or the second carrier transport layer 50 is a hole transport layer, the other of the first carrier transport layer 24 or the second carrier transport layer 50 is an electron transport layer.

The electron transport layer can be composed of a single electron transport layer or a plurality of electron transport layers. Therefore, the electron transport layer includes at least one electron transport layer comprising an electron transport material. Non-limiting examples of electron transport materials include [6,6]-phenyl-C61-butyric acid methyl ester (PCBM), Al-doped ZnO (AZO), TiO₂, bathocuproine (BCP), and combinations thereof. Accordingly, the at least one electron transport layer may be selected from the group consisting of a layer of PCBM, a layer of AZO, a layer of TiO₂, a layer of BCP, and combinations thereof. Each layer comprising the electron transport layer may have a thickness of from about 1 nm to about 500 nm.

The hole transport layer can be composed of a single hole transport layer or a plurality of hole transport layers. Therefore, the hole transport layer includes at least one hole transport layer comprising a hole transport material. Non-limiting examples of hole transport materials include poly (3,4-ethylenedioxythiophene) polystyrene sulfonate (PEDOT:PSS), poly(3-hexylthiophene-2,5-diyl) (P3HT), N,N′-Bis(naphthalen-1-yl)-N,N′-bis(phenyl)-2,2′-dimethylbenzidine (NPD), N,N′-Bis(3-methylphenyl)-N,N′-bis(phenyl)-benzidine (TPD), 2,2′,7,7′-Tetrakis(N,N-diphenylamino)-2,7-diamino-9,9-spirobifluorene (spiro-TAD), Poly[N,N′-bis(4-butylphenyl)-N,N′-bis(phenyl)-benzidine] (poly-TPD), and combinations thereof. Accordingly, the at least one hole transport layer may be selected from the group consisting of a layer of PEDOT:PSS, a layer of P3HT, a layer of NPD, a layer of TPD, a layer of sprio-TAD, a layer of poly-TPD, and combinations thereof. Each layer comprising the hole transport layer may have a thickness of from about 10 nm to about 500 nm, 15 nm to about 250 nm, or from about 20 nm to about 100 nm.

When the first carrier transport layer 24 is an electron transport layer and the second carrier transport layer 50 is a hole transport layer, such that the electron transport layer is located between the first electrode 18 and the layer comprising a metal salt 30 and the hole transport layer is located between the second electrode 56 and the layer comprising a perovskite material 36, the first electrode 18 is a cathode and the second electrode 56 is an anode. When the first carrier transport layer 24 is a hole transport layer and the second carrier transport layer 50 is an electron transport layer, such that the hole transport layer is located between the first electrode 18 and the layer comprising a metal salt 30 and the electron transport layer is located between the second electrode 56 and the layer comprising a perovskite material 36, the first electrode 18 is a anode and the second electrode 56 is an cathode. In other words, the electrode 18,56 that is located adjacent to the electron transport layer is the cathode and the electrode 18, 56 that is adjacent to the hole transport layer is the anode.

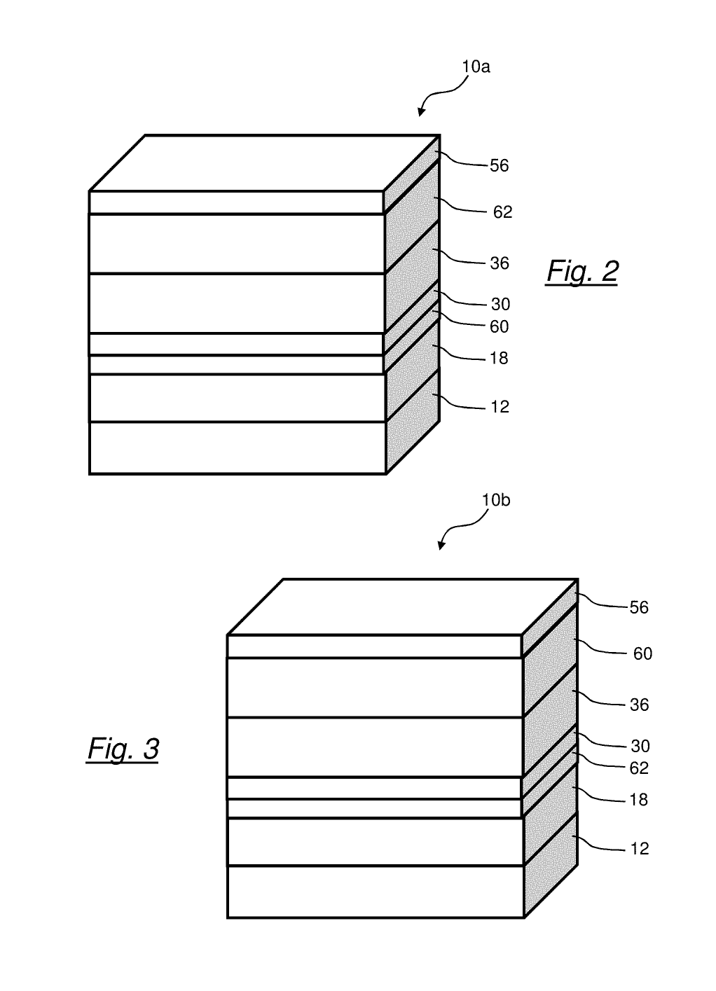

FIGS. 2 and 3 show exemplary photovoltaic devices 10a and 10b, respectively. The components of FIGS. 2 and 3 that are the same as the components of device 10 of FIG. 1 are shown with the same numerical identifiers. Neither device 10a nor 10b includes the optional second layer comprising a metal salt 42. In FIG. 2, the device 10a includes, from the bottom up, a substrate 12, a first electrode 18, an electron transport layer 60, a layer comprising a metal salt 30, a layer comprising a perovskite material 36, a hole transport layer 62, and a second electrode 56. The first electrode 18 is a cathode and the second electrode 56 is an anode. In FIG. 3, the device 10b includes, from the bottom up, a substrate 12, a first electrode 18, a hole transport layer 62, a layer comprising a metal salt 30, a layer comprising a perovskite material 36, an electron transport layer 60, and a second electrode 56. The first electrode 18 is an anode and the second electrode 56 is a cathode.

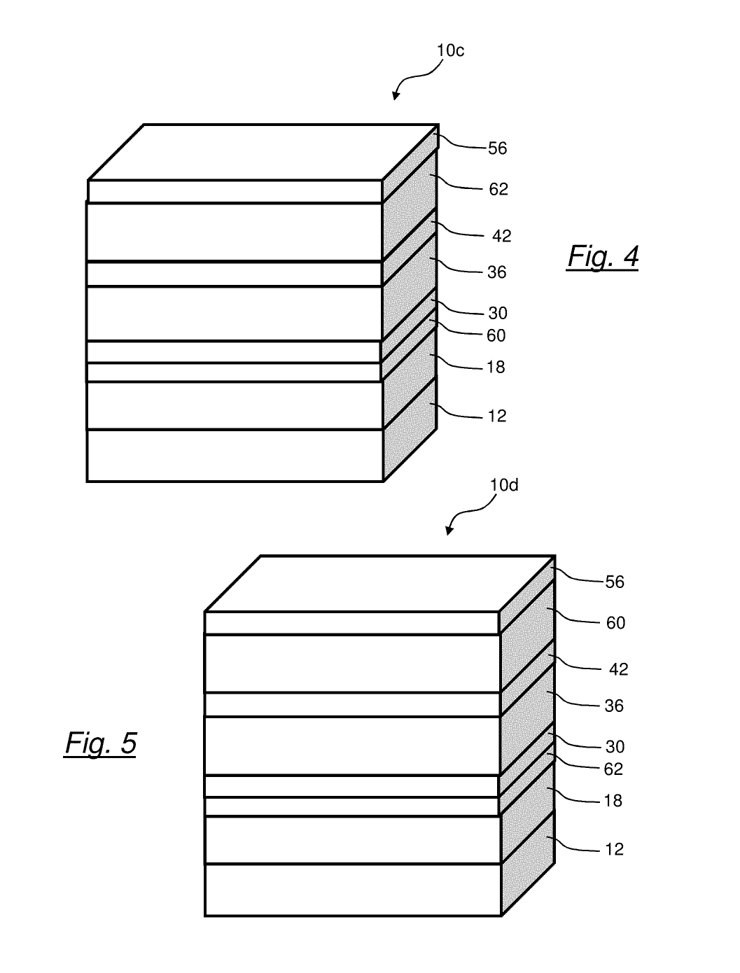

FIGS. 4 and 5 show exemplary photovoltaic devices 10c and 10d, respectively. The components of FIGS. 4 and 5 that are the same as the components of device 10 of FIG. 1, 10a of FIG. 2, or 10b of FIG. 3 are shown with the same numerical identifiers. Both devices 10c and 10d include the optional second layer comprising a metal salt 42. In FIG. 4, the device 10c includes, from the bottom up, a substrate 12, a first electrode 18, an electron transport layer 60, a layer comprising a metal salt 30, a layer comprising a perovskite material 36, a second layer comprising a metal salt 42, a hole transport layer 62, and a second electrode 56. The first electrode 18 is a cathode and the second electrode 56 is an anode. In FIG. 5, the device 10b includes, from the bottom up, a substrate 12, a first electrode 18, a hole transport layer 62, a layer comprising a metal salt 30, a layer comprising a perovskite material 36, a second layer comprising a metal salt 42, an electron transport layer 60, and a second electrode 56. The first electrode 18 is an anode and the second electrode 56 is a cathode.

As described above, the devices according to the current technology, which have a perovskite layer doped with a metal salt, demonstrate PCE and hysteresis values that are superior to devices, including other perovskite photovoltaic devices, that do not include a metal salt that is diffused into a perovskite layer.

The current technology also provides method of fabricating a doped photovoltaic device. The method comprises sequentially disposing the following layers onto a substrate: a layer comprising a first electrode, a layer comprising at least one metal salt; a layer comprising a perovskite material; and a layer comprising a second electrode. The layer comprising a perovskite material is disposed directly on the layer comprising at least one metal salt, such that the layer comprising at least one metal salt is partially or completely diffused into the layer comprising a perovskite material. The method optionally includes disposing a second layer comprising a metal salt on the layer comprising a perovskite material. In various embodiments, the method also includes disposing a first carrier transport layer onto the layer comprising a first electrode, such that the first carrier transport layer is located between the layer comprising a first electrode and the layer comprising a perovskite material. Also, the method can include disposing a second carrier transport layer onto either the optional second layer comprising a metal salt, when present, or the layer comprising a perovskite material, such that the second carrier transport layer is located between the layer comprising the perovskite material and the second electrode.

The disposing of the various layers can be performed by any means known in the art. Non-limiting examples of means for disposing the various layers include spin coating, dip coating, doctor blading, chemical vapor deposition (CVD), drop casting, spray coating, plasma-sputtering, vacuum depositing, and combinations thereof. Moreover, the layer comprising a perovskite material may be deposited additive-free in a one-step synthesis or additive-free in a two or more step synthesis. In a one-step synthesis, all perovskite reactants (e.g., PbI₂ and MAl) are deposited from one solution. A two or more-step synthesis involves the deposition of one of the reactants followed by reaction with a second reactant, either as a second deposited layer or as a gas phase diffusion process, for example.

As described above in regard to the devices, the carrier transport layers, which are either a hole transport layer or electron transport layer, may include a single layer or a plurality of layers. The layer or layers are deposited individually and sequentially.

When all the layers have been deposited, the method comprises annealing the device at a temperature of from about 75° C. to about 150° C., such as a temperature of about 90° C., from about 2 minutes to about 60 minutes or longer. In some embodiments, annealing is conducted for about 10 minutes. During the annealing, the layer comprising a metal salt and the optional second layer comprising a metal salt, when present, diffuse into the layer comprising a perovskite material. The layer comprising a metal salt and the optional second layer comprising a metal salt, when present, may partially or completely diffuse into the layer comprising a perovskite material. Therefore, the layer or layers comprising a metal salt may not be visible in the completed device with or without the aid of microscopy. This approach leads to controllable and multi-interface doping profiles.

Embodiments of the present technology are further illustrated through the following non-limiting examples.

### Example 1

A PV device including an alkali metal salt interlayer additive below a perovskite film to provide excess halide ions that can fill vacancies generated during perovskite growth and annealing is provided. The addition of an alkali metal salt layer is shown to suppress hysteresis and reliably improve performance. This method also provides a general strategy for interface doping and passivation in halide perovskite devices.

### EXPERIMENTAL

Materials and Synthesis

CH₃NH₃Cl (methyl ammonium chloride; MACl) was synthesized by mixing CH₃NH₂ (40 wt %, in deionized H₂O, Sigma) and HCl (36 wt %, in H₂O, Sigma) in a molar ratio of 1.2:1 to form a mixture. The mixture was stirred at 0° C. for 2 hrs. Then, the water was removed via rotary evaporation to yield a product, which was washed with diethyl ester until white powder was obtained. The white powder was dried in a vacuum oven at 60° C. overnight and then kept in a glove box for further use. CH₃NH₃I (methanaminium iodide; MAl) (Lumtec), Bathocuproine (BCP, Lumtec), Poly (3,4-ethylenedioxythiophene) Polystyrene sulfonate (PEDOT:PSS, Clevios PVP Al 4083, Heraeus Precious Metals), [6,6]-phenyl-C61-butyric acid methyl ester (PCBM, American Dye Source), and Al-doped ZnO (AZO) nanodispersion (Nanograde) were used as received. All the halide salts (NaCl, NaBr, NaI and Csl) were purchased from Sigma-Aldrich and used as received.

Device Fabrication

PEDOT:PSS was spin-coated onto solvent-cleaned pre-patterned ITO substrates (Xin Yan Technology) at 6000 rpm for 30 seconds and then annealed at 140° C. for 20 mins. Subsequently, alkali metal salts (NaI, NaCl, NaBr, Csl) were spin-coated onto PEDOT:PSS films at 6000 rpm for 10 seconds and annealed at 120° C. for 10 mins. CH₃NH₃PbI₃₋ₓCl precursor solutions were prepared by mixing PbI₂, MAl and MACl at a ratio of 1:1:1.5 in N,N-Dimethylformamide (DMF). The precursor solution was spin-coated onto PEDOT:PSS at 6000 rpm for 5 seconds in a nitrogen glove box to generate perovskite films. The perovskite films were annealed at 90° C. for 2 hrs unless noted otherwise. PCBM layers were coated onto the perovskite films with a solution of 20 mg/mL in chlorobenzene at 1000 rpm for 30 seconds and then annealed at 90° C. for 10 mins. A conductive AZO layer then was coated at 6000 rpm for 15 seconds using AZO nanodispersion and then annealed at 90° C. for 10 mins. Both BCP and silver electrodes were vacuum deposited at base pressures of 3×10⁻⁶ torr and a top electrode was patterned via shadowmask.

Measurement and Characterization

Current density (J) was measured as a function of voltage (V) under dark conditions and AM1.5G solar simulation (xenon arc lamp) in air, where the intensity was measured using a NREL-calibrated Si reference cell with KG5 filter. External quantum efficiency (EQE) measurements were calibrated using a Newport calibrated Si detector.

Thin film crystallinity was characterized by using a Bruker D2 Phaser XRD instrument with a Ni filter in the Bragg-Brentano configuration. SEM was carried out via a Carl Zeiss Auriga Dual Column FIB SEM at 20 kV accelerating voltage.

Transfer Matrix Optical Modeling

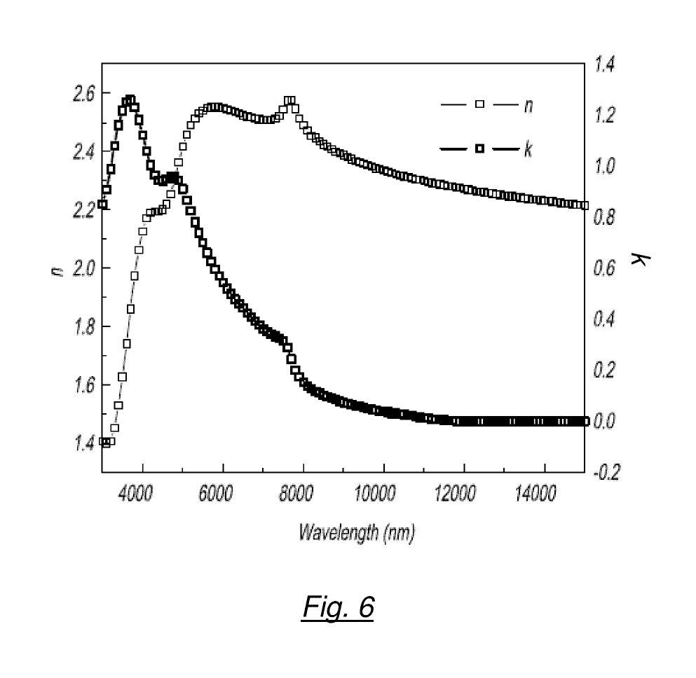

Optical constants of perovskite layers used in optical modeling were determined with variable angle ellipsometry (see FIG. 6). Transfer matrix modeling was performed at normal incidence using a custom Matlab code outlined elsewhere. For reference, the generation rate (G) is related to electric field as:

$$G = \frac{1}{2} c {ɛ}_{0} {n}_{j} {α}_{j} {\vert {E}_{j} \vert}^{2} ,$$

where c is the speed of light, ε₀ is the permittivity of free space, nⱼ is the index of refraction in layer j, αⱼ is the absorption coefficient in layer j.

Grain Size Estimation

The grain size is estimated based on the Scherrer equation, D=Kλ/β cost θ, where D is the volume average grain size in the normal direction, λ is the x-ray wavelength, β is peak breadth at full-width-half-maximum (FWHM) after subtracting the instrumental peak breadth, θ is the Bragg diffraction angle, and K is a dimensionless shape factor that is set to 1 by the definition of the peak breath below. Considering the Gaussian shape of the diffraction peaks, the peak breadth is then β²=π/(4 ln(2))·(Γ_{Meas}²−Γ_{Ins}²), where Γ_{Meas} is the FWHM for the measured sample and Fᵢₙₛ is the instrumental FWHM.

Results and Discussion

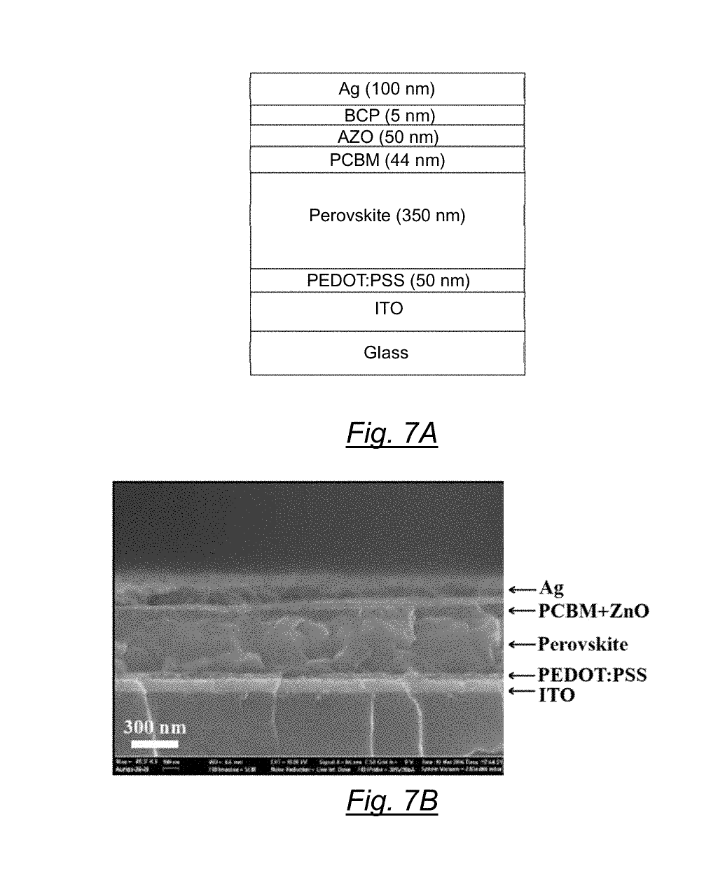

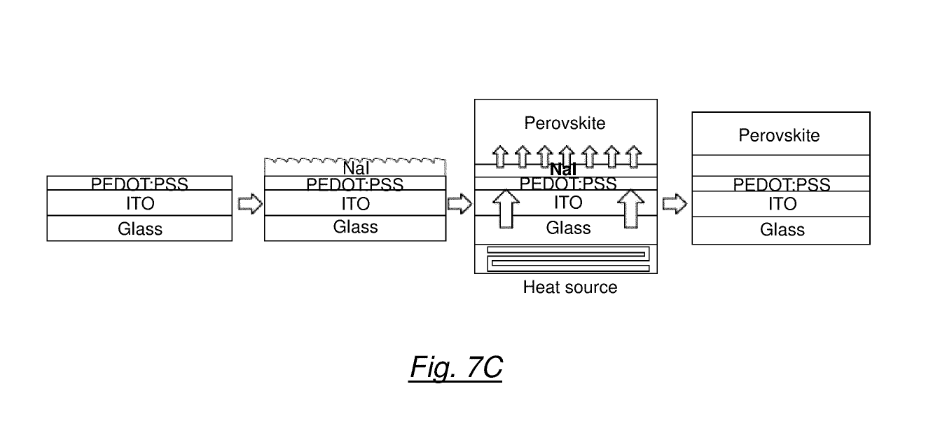

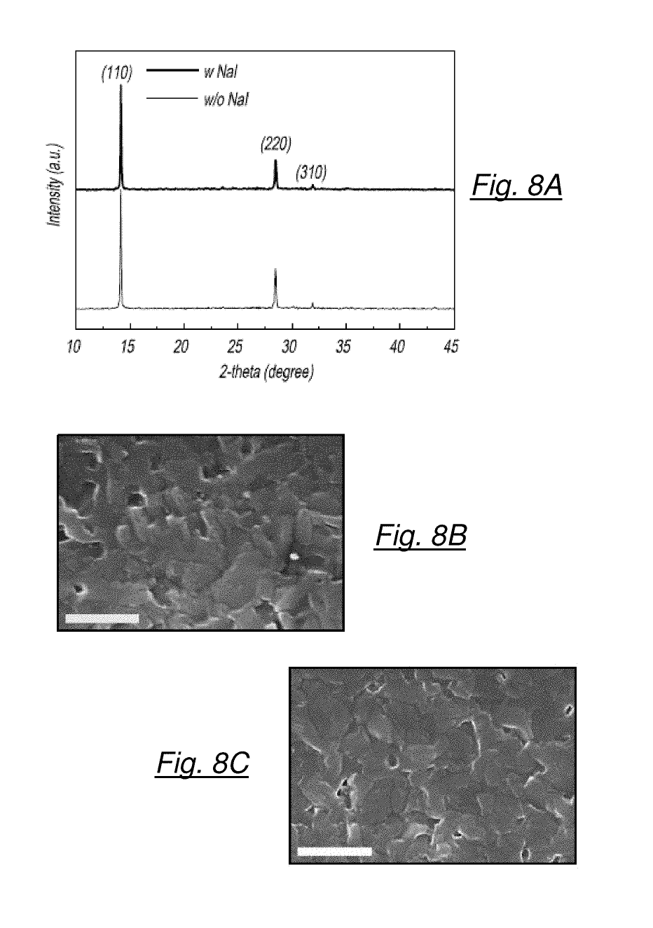

A perovskite device schematic and SEM image of a fabricated device are shown in FIG. 7A and a micrograph of the fabricated device is shown in FIG. 7B. The approach for preparing samples with alkali metal salt interlayers is shown in FIG. 7C. Because the annealing by heat generated from the heat source causes the NaI to diffuse into the perovskite, the layer of NaI is not optically visible in FIG. 7B. Structural characteristics measured with x-ray diffraction (XRD) and scanning electron microscopy (SEM) are shown in FIGS. 8A-8C for samples prepared with and without the salt interlayer (NaI), respectively. Both samples show only a preferred (110) crystal orientation with no detectable presence of unreacted phases. Comparing FIG. 8B to FIG. 8C, metal halides salts are shown to help decrease the pin-holes in perovskite films but otherwise do not impact morphology.

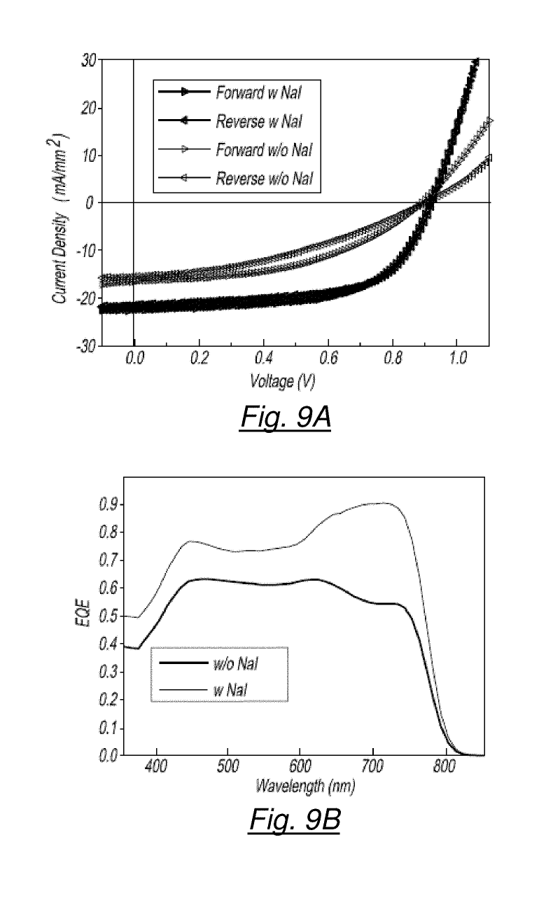

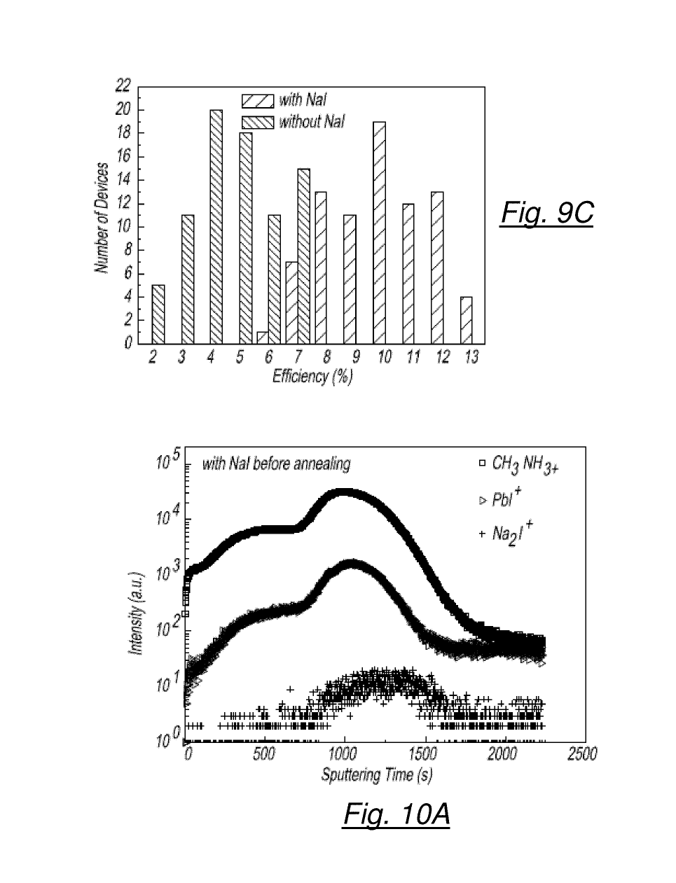

The current density-voltage (J-V) characteristics of champion devices with, and without NaI, under forward and reverse scans are shown in FIGS. 9A-9C along with external quantum efficiencies and detailed statistics of device performance. Table 1 provides a summary of J-V parameters and hysteresis data. By introducing a NaI layer, a near doubling in the PCE from 6.8% to 12.6% is observed. Additionally, the hysteresis for samples is calculated by comparing the difference of PCE obtained under forward and reverse scan, respectively. This difference highlights that the hysteresis of samples prepared with NaI is reduced from 30.8% to only 1.6%. Adding NaI significantly enhances the EQE at all wavelengths with greater enhancement at longer wavelength.

TABLE 1
Parameters of J-V characteristics and hysteresis of
champion devices prepared with or without NaI, respectively.
The hysteresis is calculated by dividing the PCE obtained
under reverse scan with the PCE difference between forward
scan and reverse scan.

| | Scan | Jsc | Voc | | η | Hysteresis |
|---|---|---|---|---|---|---|
| | direction | (mA/cm²) | (V) | FF | (%) | (%) |
| with | Forward | −22.4 ± 2.2 | 0.92 ± 0.01 | 0.61 ± 0.01 | 12.6 ± 1.3 | −1.6% |
| NaI | Reverse | −21.5 ± 2.1 | 0.93 ± 0.01 | 0.62 ± 0.01 | 12.4 ± 1.2 | |
| without | Forward | −16.6 ± 1.7 | 0.89 ± 0.01 | 0.46 ± 0.01 | 6.8 ± 0.7 | −30.8% |
| NaI | Reverse | −15.5 ± 1.5 | 0.90 ± 0.01 | 0.37 ± 0.01 | 5.2 ± 0.5 | |

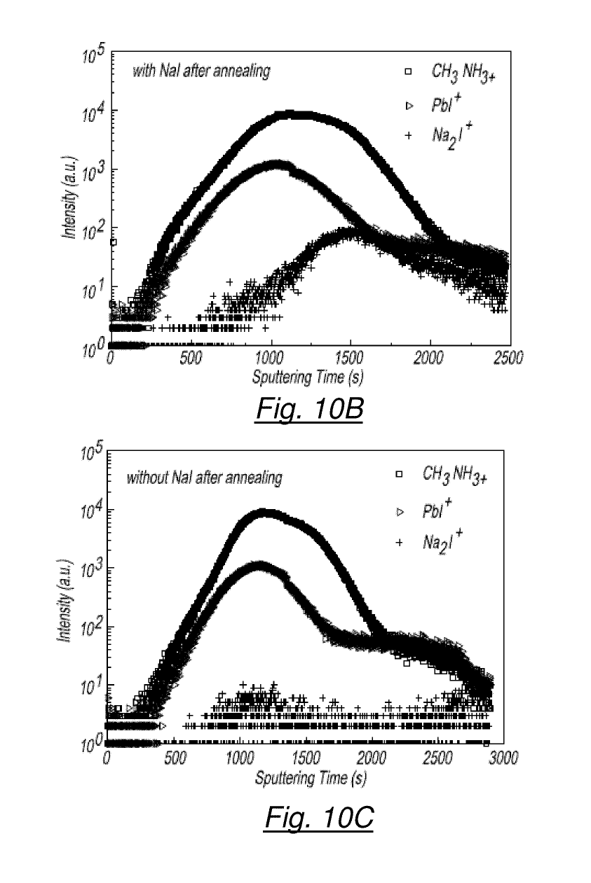

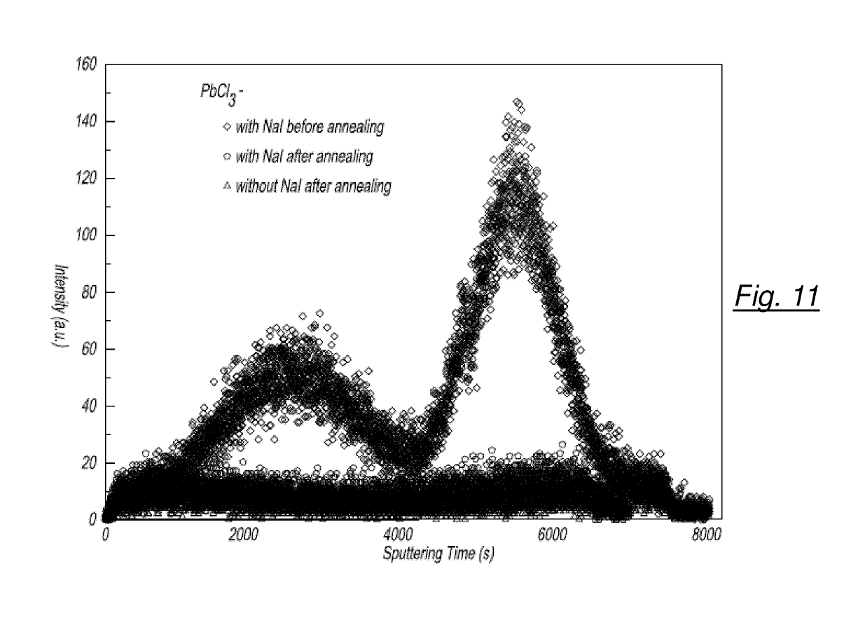

To understand the mechanism by which NaI improves the device performance, TOF-SIMS depth profile was performed to determine the element distribution, where both negative and positive ions were determined. Table 2 shows selected ion profiles through the device stack. Comparing FIG. 10A to FIG. 10B, shows that after annealing, the weak peak of PbI⁺ moves towards the PCBM side, which is assigned to unreacted PbI₂. It further indicates that during the annealing process essentially all of the chloride and some of the iodide evaporate and partially escape from the perovskite surface (see FIG. 11 for the detection of chlorine). Furthermore, the change of Na₂I⁺ peak shows that there is a broader distribution of Na in the unannealed sample than in the annealed sample which implies that the NaI distributes more uniformly with the initial deposition and then migrates to the PEDOT/perovskite interface during annealing. Correspondingly, the peak of CH₃NH₃⁺ assigned to perovskite has been broadened by adding NaI as shown in FIG. 10B and FIG. 10C. Therefore, comparing to the sample prepared without NaI, the iodide vacancies inside the sample prepared with NaI have largely been suppressed.

TABLE 2
The selected ion with their mass and the compound they are
assigned to.

| Ion | Center of mass (amu) | Attribution |
|---|---|---|
| CH₃NH₃⁺ | 32.0486 | Perovskite |
| PbI⁺ | 334.8885 | PbI₂ |
| Na₂I⁺ | 172.8703 | NaI |

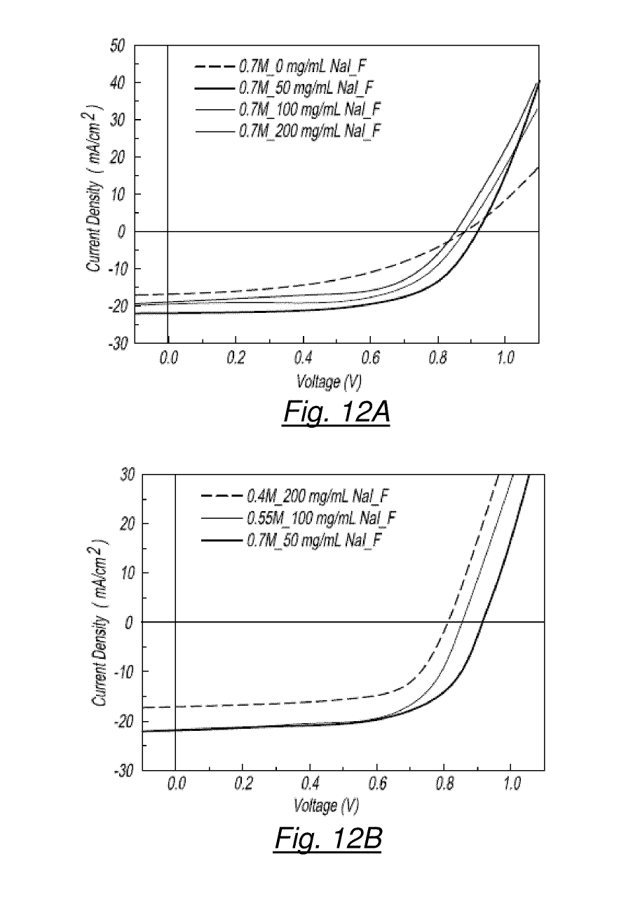

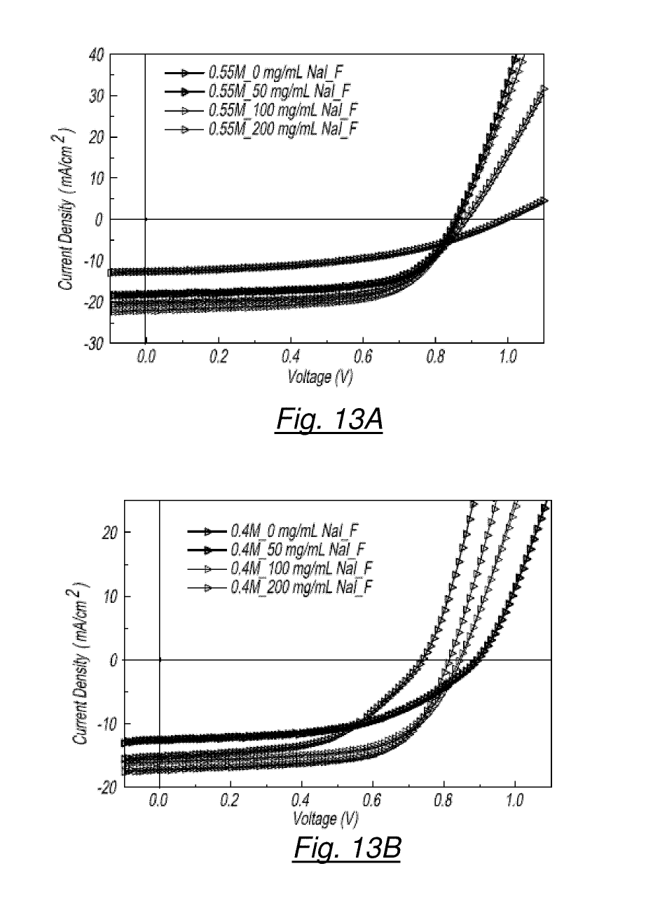

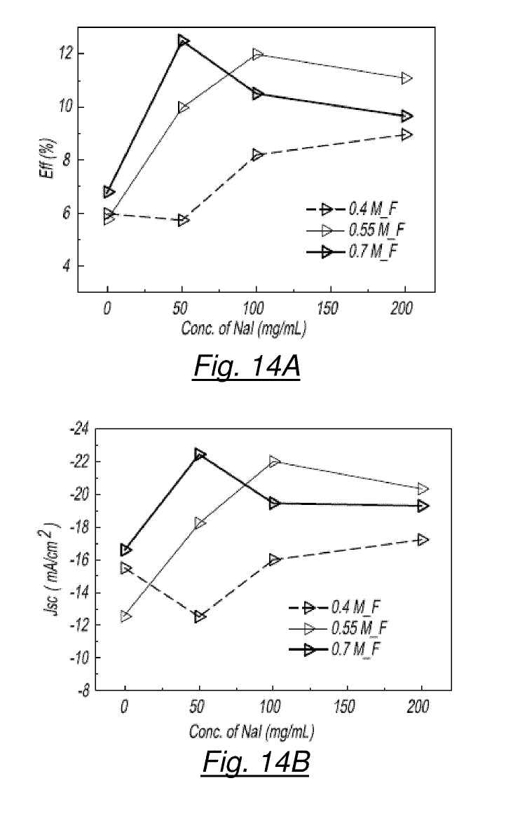

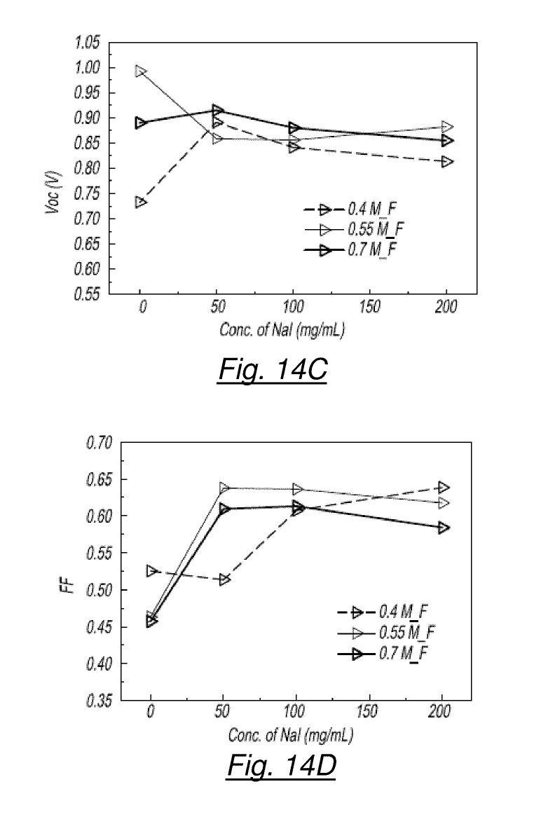

To systematically study the effect of NaI, the concentration of NaI, perovskite precursor solution, and the type of alkali metal salts were tuned. FIGS. 12A and 12B show the J-V characteristics of devices fabricated with different NaI concentrations (which translates to different NaI thicknesses) using 0.7 M of perovskite precursor solution. Interestingly, with increasing concentration of perovskite precursor solution from 0.4 M to 0.7 M, the optimized thickness of NaI decreases (see FIGS. 13A-13B for performance of devices fabricated with different perovskite precursor concentration). This optimized thickness is due to the lower solubility of NaI in perovskite precursor solutions with higher concentration which can result in an excess of NaI left at the interface. Table 3 provides a summary of J-V parameters and hysteresis data for samples prepared with different annealing parameters. FIG. 14A-14D shows the changes of J-V parameters with the concentration of NaI for different concentration of the precursor solution. Without NaI, the efficiency is about half of that with optimized NaI concentration and both the values of Jsc and FF decrease substantially during reverse scan, while Voc always increases. By adding NaI, especially for the optimized concentration, Jsc, Voc and FF changes very slightly between forward scan and reverse scan, which results in very little hysteresis.

TABLE 3
Parameters of J-V characteristics and hysteresis of samples prepared
with different annealing parameters. The hysteresis is calculated by dividing the
efficiency obtained under reverse scan with the efficiency difference between
forward scan and reverse scan.

| Conc. | Annealing | Scan | Jsc | Voc | | η | Hysteresis |
|---|---|---|---|---|---|---|---|
| of NaI | parameter | direction | (mA/cm²) | (V) | FF | (%) | (%) |
| 100 mg/mL | 90° C. for | Forward | −19.5 ± 1.9 | 0.88 ± 0.01 | 0.61 ± 0.01 | 10.5 ± 1.1 | 4.5 |
| | 2 hrs | Reverse | −19.5 ± 1.9 | 0.88 ± 0.01 | 0.64 ± 0.01 | 11.0 ± 1.1 | |
| | 100° C. for | Forward | −17.5 ± 1.7 | 0.89 ± 0.01 | 0.54 ± 0.01 | 8.4 ± 0.8 | −18.3 |
| | 2 hrs | Reverse | −15.9 ± 1.6 | 0.93 ± 0.01 | 0.48 ± 0.01 | 7.1 ± 0.7 | |
| | 100° C. for | Forward | −15.1 ± 1.5 | 0.93 ± 0.01 | 0.43 ± 0.01 | 6.0 ± 0.6 | −42.9 |
| | 2.5 hrs | Reverse | −12.5 ± 1.3 | 0.97 ± 0.01 | 0.35 ± 0.01 | 4.2 ± 0.4 | |
| 200 mg/mL | 90° C. for | Forward | −19.3 ± 1.9 | 0.86 ± 0.01 | 0.58 ± 0.01 | 9.6 ± 1.0 | 9.4 |
| | 2 hrs | Reverse | −19.6 ± 2.0 | 0.87 ± 0.01 | 0.62 ± 0.01 | 10.6 ± 1.1 | |
| | 100° C. for | Forward | −18.0 ± 1.8 | 0.94 ± 0.01 | 0.53 ± 0.01 | 9.0 ± 0.9 | −5.9 |
| | 2 hrs | Reverse | −17.7 ± 1.8 | 0.96 ± 0.01 | 0.50 ± 0.01 | 8.5 ± 0.9 | |
| | 100° C. for | Forward | −14.8 ± 1.5 | 0.96 ± 0.01 | 0.48 ± 0.01 | 6.8 ± 0.7 | −44.7 |
| | 2.5 hrs | Reverse | −12.6 ± 1.3 | 0.99 ± 0.01 | 0.38 ± 0.01 | 4.7 ± 0.5 | |

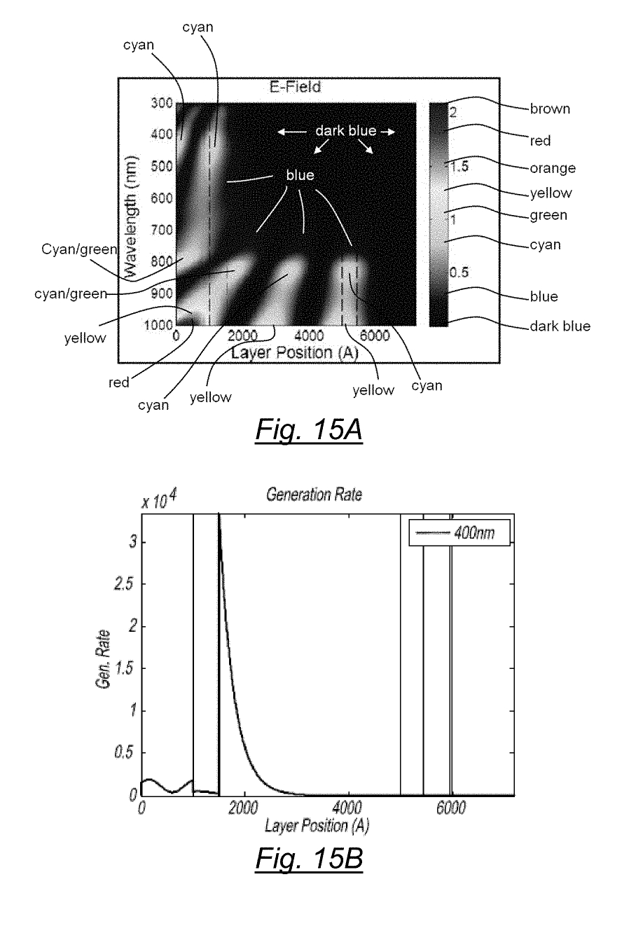

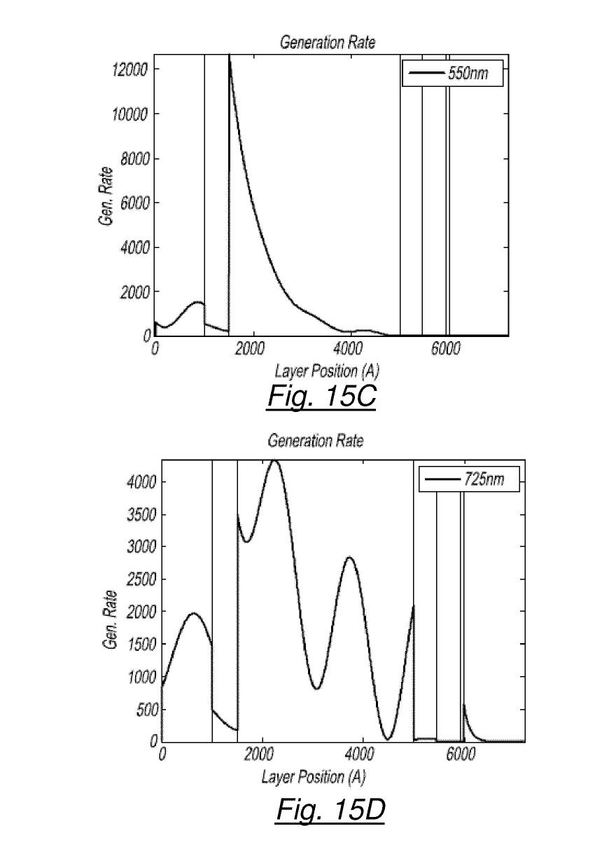

To further understand the mechanism involved in the EQE improvement, an optical transfer matrix model was employed to study the change of position-dependent light absorption and excited state generation. FIGS. 15A-15D illustrate the simulated incident light wavelength and layer position-dependent photon absorption rates under AM1.5G solar photon reflux for a complete device as shown in FIGS. 7A and 7B. The layer position-dependent exciton generation rate at 400 nm, 550 nm and 725 nm, which respectively represent shorter, medium and longer wavelengths, is also shown. This data shows that the generation rate is greatest near the PEDOT/perovskite interface at 400 nm and 550 nm, showing an exponential decay with position when the absorption coefficient is large. At longer wavelength, when the absorption coefficient is smaller, the generation rate shows more complex absorption profiles. The absorption profile still has a peak generate rate near the PEDOT/perovskite interface but also shows a substantial absorption peak near the middle of the perovskite layer. Hence, the reduction of iodide vacancies from the addition of NaI improves the EQE for all wavelengths. However, the greater enhancement of the long wavelength EQE then indicates that there is a greater relative density of defects that are eliminated by residual NaI near the middle of the device that results in greater enhancement of long-wavelength photocurrent. This observation is consistent with the depth-profiled TOF-SIMS measurements which show that while the NaI distribution is concentrated towards the interface after annealing, there is still some distribution through most of the device. This device modeling also highlights the key importance of the PEDOT/perovskite interface, where the vast majority of excited states are generated and dissociated and the greater importance of having a high electron diffusion length.

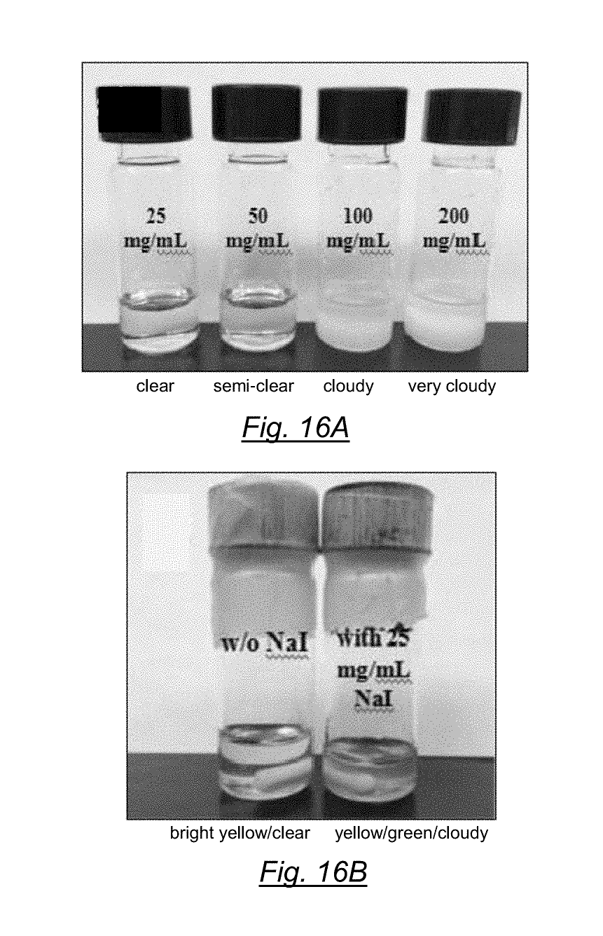

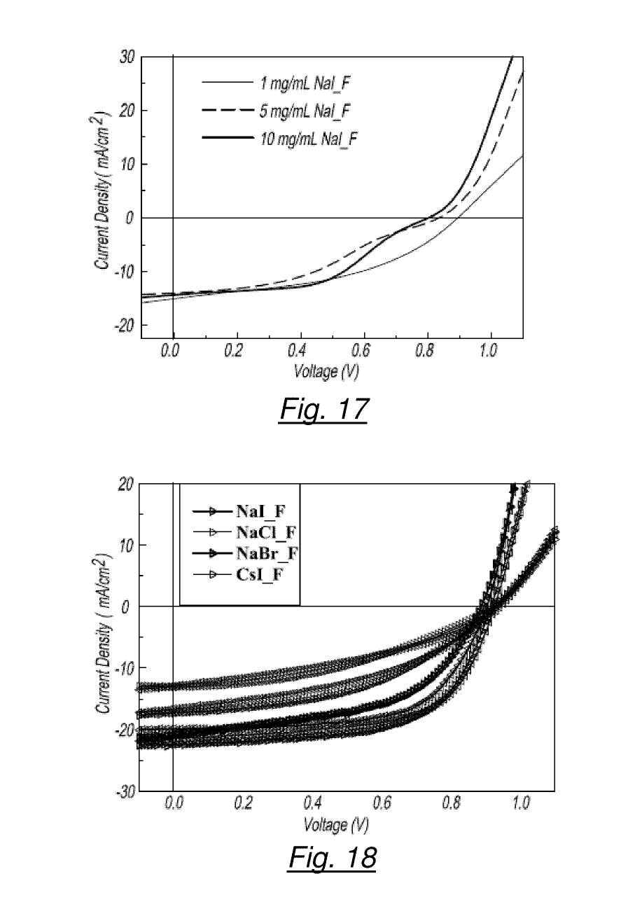

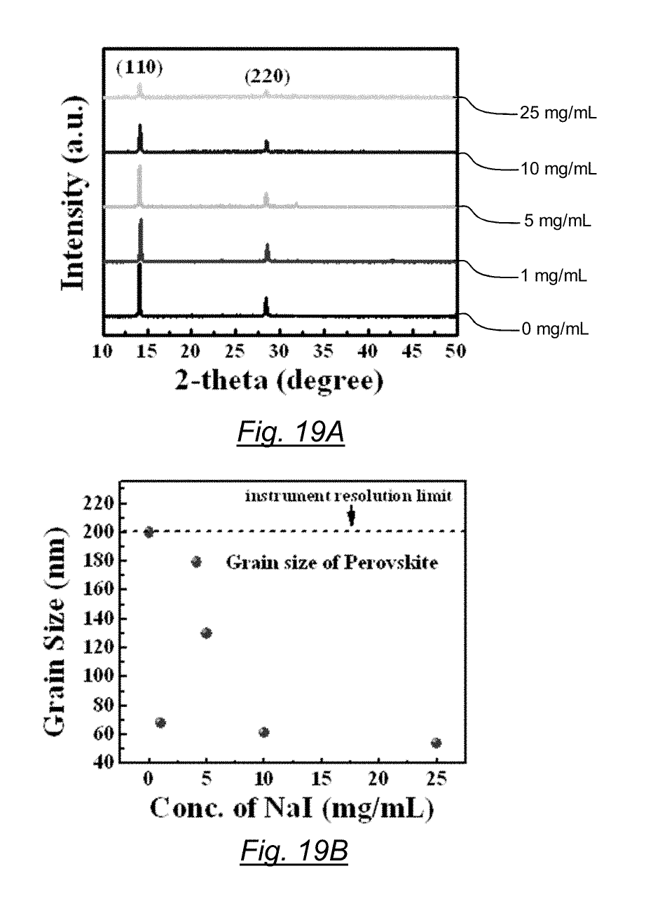

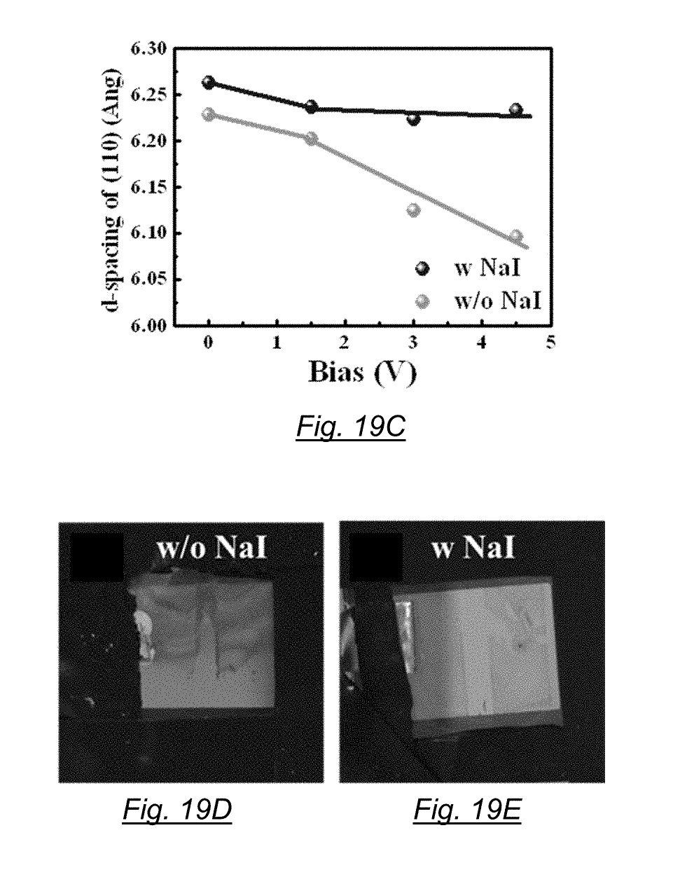

For comparison to neat layer NaI deposition, devices with the direct co-deposition of NaI with perovskite from precursor solutions (see FIGS. 16A-16B) were tested. Importantly, the devices fabricated with co-deposition do not show enhanced performance—rather the emergence of an S-shape J-V data that indicates large series resistance (see FIG. 17) was observed. Combined with the TOF-SIMS results, these data suggest that the resulting impact on the crystallization of the perovskite limit the impact of the metal halide addition. To confirm the impact of NaI co-deposition on the crystallization of perovskite film, samples prepared with NaI co-deposition were characterized with XRD. As shown in FIGS. 17 and 18, increasing the NaI concentration in the precursor solution results in weaker intensity of (110) peak and greater full width at half maximum (FWHM). Considering the instrument limited peak breadth, the grain size in the normal direction of samples prepared without NaI is close to upper limit resolution of this measurement (200 nm) and the film thickness (e.g., 350 nm). In contrast, and with reference to FIGS. 19A and 19B, the grain size in the normal direction of samples prepared with NaI co-deposition is found to be roughly ⅓ of the size of the film thickness. This implies that when co-deposited with perovskite precursors (rather than diffused from the interface), the NaI causes poor grain formation that leads carriers to have to traverse multiple grain boundaries to reach the electrodes, in contrast to previous work with the co-deposition of dopants into the perovskite precursors. This is then consistent with poor and resistive device performance.

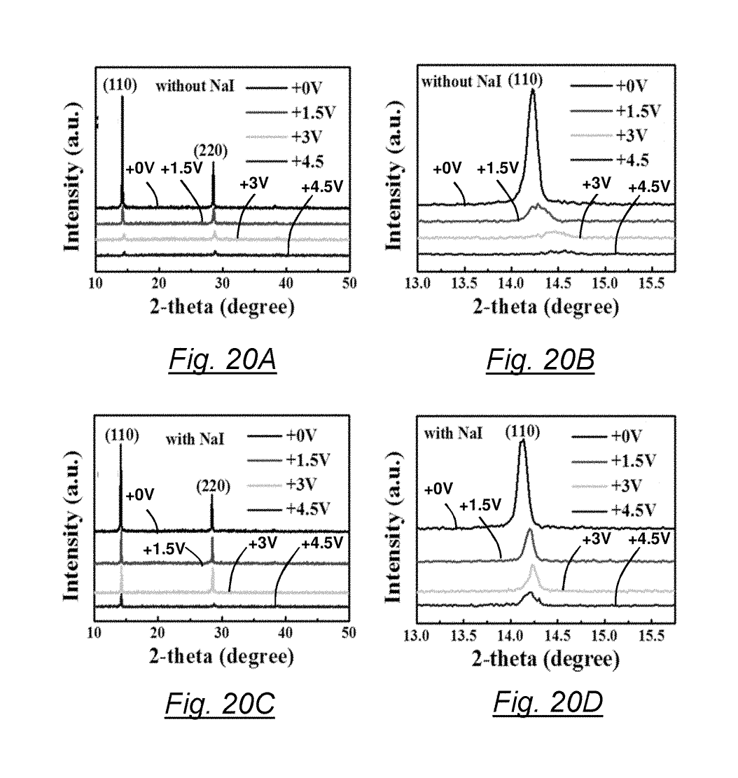

To further confirm the reduction of iodide vacancies by the introduction of the NaI interlayer, XRD patterns were collected during applied bias to investigate the crystal structure change of samples prepared with, or without, NaI as shown in FIG. 19C for the (110) d-spacing. Also, FIGS. 20A-20D show full XRD patterns under bias. More particularly, FIG. 20A shows an XRD pattern for a sample fabricated without NaI, FIG. 20B is an enlarged view of the XRD pattern shown in FIG. 20A, FIG. 20C shows an XRD pattern for a sample fabricated with NaI, and FIG. 20D is an enlarged view of the XRD pattern shown in FIG. 20C. The data in FIG. 19C shows that the (110) peak shifts to smaller d-spacings in both samples when applied bias changes from 0V to +1.5V. However, for the sample prepared with NaI interlayer, the peak shift is minimal when further increasing bias from +1.5V to +4.5V, whereas the sample without NaI continues to decrease. Considering Vegard's law it is expected that an increase in the vacancy concentration would lead to smaller lattice constants particularly under electrostrictive bias. The lattice constant of the sample prepared with the NaI interlayer is always larger than that prepared without NaI and shows a bias dependence over a much larger range, clearly indicating that NaI interlayer helps to reduce iodide vacancies. FIGS. 19D and 19E are photographs showing the appearance of samples prepared without and with NaI, respectively, after applying bias.

Previous research has demonstrated that iodide migration via vacancies leads to hysteresis. Furthermore, such ion migration may also result in trap states which can trap charge carriers and cause charge accumulation. Therefore, during J-V data collection, either ion accumulation caused by iodide migration or charge carrier trapped at these trap states can be driven by the eternal bias. Such ion migration or carrier trapping/detrapping results in an internal electric field change and further affect the charge carrier collection at the interface, which can affect the J-V characteristic parameters including Voc, Jsc and FF.

A range of metal halide salts including NaCl, NaBr and Csl, as shown in FIG. 18, were also tested. Among these salts, samples prepared with NaBr show the similarly high performance to NaI despite the lingering presence of some hysteresis. The reduction in performance of the remaining salts could be due to a combination of changes in solubility in DMF (used to deposit the perovskite), initial salt morphology, trap passivation capacity, or formation of new trap states. In terms of processing, the solubility of each salt in DMF is actually an important consideration because it can lead to an excess of neat salt layers left behind that result in higher series resistance in devices. This is likely at least part of the reason NaCl film shows poorer device performance (see FIG. 18), but could also be related to Cl⁻ ions being easily lost from films during annealing. Thus, there are a number of factors that can ultimately play a role in the optimization of metal halide salt additives for improving perovskite devices and the choice of perovskite solvent could ultimately alter this optimization.

### CONCLUSION

A new method to suppress the hysteresis in the J-V characteristics of lead-halide perovskite devices was developed. In this method, alkali metal salts were introduced as interlayers that distribute during perovskite formation. By decreasing the halide ion vacancies, the hysteresis caused by charge accumulation at the interface of perovskite and transporting layer has been significantly suppressed. Utilizing this approach with NaI device performance was shown to be improved by filling iodide vacancies with PCEs of up to 12.6% with little hysteresis. Furthermore, such method also provides a general route of doping process for perovskite-based device, in which the dopants can be separated from precursor solution. By decoupling the dopant from the perovskite solution, these were shown to be viable dopants for enhancing performance. This approach provides new pathways for the doping of a wide range of perovskites.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. A photovoltaic device comprising:
a substrate comprising a first surface and a second opposing surface;
a first electrode disposed directly on at least one of the first surface or the second surface of the substrate;
a layer comprising a perovskite material;
a layer comprising a metal salt; and
a second electrode,
wherein the layer comprising a metal salt and the layer comprising a perovskite material are located between the first electrode and the second electrode.

2. The photovoltaic device according to claim 1, wherein the metal salt is a metal halide salt selected from the group consisting of PbX₂, SnX₂, GeX₂, AlX₃, BX₃, GaX₃, BiX₃, InX₃, SiX₄, TiX₄, SbX₅, and combinations thereof, where X is a halide or a combination of halides.

3. The photovoltaic device according to claim 1, wherein the metal salt is at least one alkali metal halide salt having the formula MX, where M is Li, Na, K, or Rb and X is a halide or a combination of halides.

4. The photovoltaic device according to claim 3, wherein the metal salt is NaI, NaBr, or a combination thereof.

5. The photovoltaic device according to claim 1, wherein the metal salt is at least one alkaline earth metal salt having the formula M′X₂, where M′ is Be, Mg, Ca, or Sr an X is a halide.

6. The photovoltaic device according to claim 1, wherein the metal salt is at least one transition metal halide salt having the formula MXₙ, where M is Mn, Fe, Co, Ni, Cr, V, or Cu; n is 1, 2, 3, 4, or 5; and X is a halide.

7. The photovoltaic device according to claim 6, wherein the transition metal halide salt is selected from the group consisting of MnF₃, MnF₄, MnCl₂, MnCl₃, MnBr₂, Mnl₂, FeF₂, FeF₃, FeCl₃, FeCl₂, FeBr₂, FeBr₃, Felₜ, Fel₃, CoF₂, CoF₃, CoF₄, CoCl₂, CoCl₃, CoBr₂, CoI₂, NiF₂, NiCl₂, NiI₂, CrF₂, CrF₃, CrF4, CrF5, CrF₆, CrCl₂, CrCl₃, CrCl₄, CrBr₂, CrBr₃, CrBr₄, CrI₂, CrI₃, CrI₄, VF₂, VF₃, VF₄, VF₅, VCl₂, VCl₃, VCl₄, VBr₂, VBr₃, VBr₄, VI₂, VI₃, VI₄, CuF, CuF₂, CuCl, CuCl₂, CuBr₂, CuI, and combinations thereof.

8. The photovoltaic device according to claim 1, wherein the metal salt is at least one sulfide salt having the formula M₂S, M'S, M″₂S₃, or M*S₂, where M is Li, Na, K, or Rb; M′ is Be, Mg, Ca, Sr, or Pb; M″ is Bi, Al, Ga, In, or Sb; M* is Si, Ge, Sn, or Pb; and S is S, Se, or Te.

9. The photovoltaic device according to claim 1, wherein the layer comprising a perovskite material comprises at least one hybrid halide perovskite having the formula ABX₃, where A is methylammonium (MA), formamidinium (FA), ethanediammonium (EA) or iso-propylammonium; B is Pb, Sn, Ge, Cu, Sr, Ti, Mn, or Zn; and X is a halide.

10. The photovoltaic device according to claim 1, wherein the layer comprising a perovskite material comprises at least one inorganic halide perovskite having the formula MBX₃, where M is Li, Na, K, Rb, or Cs; B is Pb, Sn, Ge, Cu, Sr, Ti, Mn, or Zn; and X is a halide.

11. The photovoltaic device according to claim 1, further comprising:
a carrier transport layer, wherein the carrier transport layer is disposed directly on the layer comprising a perovskite material.

12. The photovoltaic device according to claim 11, wherein the carrier transport layer comprises either at least one electron transport layer selected from the group consisting of a layer of [6,6]-phenyl-C61-butyric acid methyl ester (PCBM), a layer of Al-doped ZnO (AZO), a layer of TiO₂, a layer of bathocuproine (BCP), and combinations thereof, or at least one hole transport layer selected from the group consisting of a layer of poly (3,4-ethylenedioxythiophene) polystyrene sulfonate (PEDOT:PSS), a layer of poly(3-hexylthiophene-2,5-diyl) (P3HT), and combinations thereof.

13. The photovoltaic device according to claim 11, wherein the carrier transport layer is an electron transport layer, the second electrode is a cathode, and the electron transport layer is disposed on the cathode, such that the electron transport layer is located between the layer comprising a perovskite material and the cathode.

14. The photovoltaic device according to claim 13, wherein the cathode comprises at least one conducting material selected from the group consisting of LiF/Al, Au, Ag, Al, Cu, Cr, In, Li, Mg, W, Zn, Ni, a metal oxide, a transparent conducting oxide, a transparent conducting graphene thin film, a transparent conducting nanotube film, a transparent ultrathin metal, a metal, metal nanowires, and combinations thereof.

15. The photovoltaic device according to claim 1, further comprising:
a carrier transport layer, wherein the carrier transport layer is disposed directly on the layer comprising a metal salt, such that the layer comprising a metal salt is located between the layer comprising a perovskite material and the carrier transport layer.

16. The photovoltaic device according to claim 1, wherein the layer comprising a metal salt has an initial thickness of from about 0.1 nm to about 100 nm thick and becomes partially or completely diffused in the layer comprising a perovskite material.

17. A method for fabricating a doped photovoltaic device, the method comprising sequentially disposing the following layers onto a substrate:
a layer comprising a first electrode;
a layer comprising at least one metal salt;
a layer comprising a perovskite material; and
a layer comprising a second electrode,
wherein the layer comprising a perovskite material is disposed directly on the layer comprising at least one metal salt, such that the layer comprising at least one metal salt is partially or completely diffused into the layer comprising a perovskite material.

18. The method according to claim 17, wherein the layer comprising a perovskite material is disposed additive-free in a one-step synthesis.

19. The method according to claim 17, wherein the layer comprising a perovskite material is disposed additive-free in a two or more step synthesis.

20. The method according to claim 17, wherein the disposing a layer comprising at least one metal salt comprises disposing at least one metal salt selected from the group consisting of a metal halide salt, an alkali metal salt, an alkaline earth metal salt, a transition metal halide salt, a sulfide salt; and a combination thereof, and the method further comprises:
annealing the layers,
wherein the annealing induces diffusion of the layer comprising at least one metal salt into the layer comprising a perovskite material.
